(19) United States
(12) Patent Application Publication
(10) Pub. No.: US 2014/0299348 A1
(43) Pub. Date: Oct. 9, 2014

(54) DATA TRANSMISSION CABLE INTENDED FOR THE AERONAUTICAL INDUSTRY

(71) Applicant: NEXANS, PARIS (FR)

(72) Inventor: Thiery Daumand, Guignen (FR)

(21) Appl. No.: 14/225,695

(22) Filed: Mar. 26, 2014

(30) Foreign Application Priority Data
Apr. 8, 2013 (FR) FR 13 53136

(51) Int. Cl. H05K 9/00; H01B 1/06; H01B 1/02

(52) U.S. Cl. CPC H05K 9/0098; H01B 1/02; H01B 1/06
USPC 174/107

(57) ABSTRACT

A data transmission cable includes four bundles (10) each having 19 copper conductor wires and each covered with an insulating layer (12). A shielding (14) has a metallic copper fabric and an outer sheath (15). The diameter of each bundle (10) is equal to 0.625 mm with a tolerance of plus or minus 0.007 mm, where the insulating layer (12) includes an aerated material, this aeration representing 40% of its total volume. The cable has no central mechanical support strength member for the bundles (10) and no separating tape around the bundles (10).

### RELATED APPLICATION

This application claims the benefit of priority from French Patent Application No. 13 53136, filed on Apr. 8, 2013, the entirety of which is incorporated by reference.

### BACKGROUND

1. Field of the Invention

The invention relates to a transmission cable with copper conductor wires, intended for she aeronautical industry, in particular a cable for Ethernet application.

2. Description of Related Art

Such a known cable is marketed by the applicant under the reference EN 3375-011 C KL and is represented in FIG. 1.

From inside to outside, this cable comprises:
a central mechanical support strength member 6,
four bundles 1 bundled around this central strength member and each consisting of 19 silver-coated copper conductor wires, the nominal diameter of each bundle being 0.60 mm, and covered with a colored insulating layer 2 made of fluoropolymer,
a separator tape 3 made of polytetrafluoroethylene (commonly known by its abbreviation PTFE),
a shielding 4 consisting of a metallic fabric of silver-coated braided copper wires and in which the diameter of the braided wires is 0.10 mm,
an outer sheath 5 made of fluoropolymer.

The outer diameter of this cable is of the order of 3.85 mm.

Moreover, the maximum. attenuation at 25° C. of such a cable is defined by the standard published by the European Association of Aeronautical Industries (AECMA) with the reference EN 3375-011 and published in September 2012.

These maximum allowable attenuation levels are defined in table 4 of this standard and are:

| Frequency | Maximum cable attenuation |
|---|---|
| (MHz) | (dB/100 m) |
| 1.00 | 2.1 |
| 4.00 | 4.4 |
| 10.00 | 6.9 |
| 16.00 | 8.8 |
| 20.00 | 9.9 |
| 31.25 | 12.5 |
| 62.50 | 18 |
| 100.00 | 23.3 |

### OBJECTS AND SUMMARY

The object of the invention is to optimize such a cable by reducing the attenuation of a data transmission cable with copper conductor wires, intended for the aeronautical industry.

For this, the invention proposes a data transmission cable, comprising four bundles each consisting of 19 copper conductor wires and each covered with an insulating layer, a shielding consisting of a metallic copper fabric and an outer sheath, characterized in that
the diameter of each said bundle is equal to 0.625 mm with a tolerance of plus or minus 0.007 mm,
said insulating layer comprises an aerated material, this aeration representing 40% of its total volume,
it has no central mechanical support strength member for said bundles and no separating tape around said bundles.

In addition to a reduction of the attenuation, the cable according to the invention also has a total maximum linear weight of 32 kg/km, which is particularly favorable.

According to a preferred embodiment, said insulating layer is provided with longitudinal aeration cells.

It can also be made up of an insulating foam material, such as, for example, fluorinated ethylene propylene (commonly known by its abbreviation FEP), per-fluoro-alkoxy or ethylene tetrafluoroethylene (ETFE).

It can also consist of an aerated extrusion material, for example polytetrafluoroethylene (PTFE).

It can finally consist of a taped material, for example of low density polytetrafluoroethylene (PTFE LD).

Preferably, said insulating layer has no coloring pigments and is coated with a colored skin.

Said colored, skin is preferably approximately 0.05 mm. thick.

Said shielding consisting of a metallic fabric preferably comprises braided wires with a diameter of approximately 0.12 mm.

Said conductor wires and said braided wires are advantageously coated with silver.

Preferably, the silver coating of said conductor wires has a minimum thickness of 1 micron.

Said outer sheath is advantageously made of ethylene tetrafluorflethylene, also called poly(ethylene-co-tetrafluoroethylene), commonly known by its abbreviation ETFE.

### BRIEF DESCRIPTION OF THE DRAWINGS

The invention is described hereinbelow in more detail with the aid of a figure representing only a preferred embodiment of the invention.

FIG. 1, already detailed, is a cross-sectional view of a known cable according to the prior art.

FIG. 2 is a cross-sectional schematic view of a cable according to the invention.

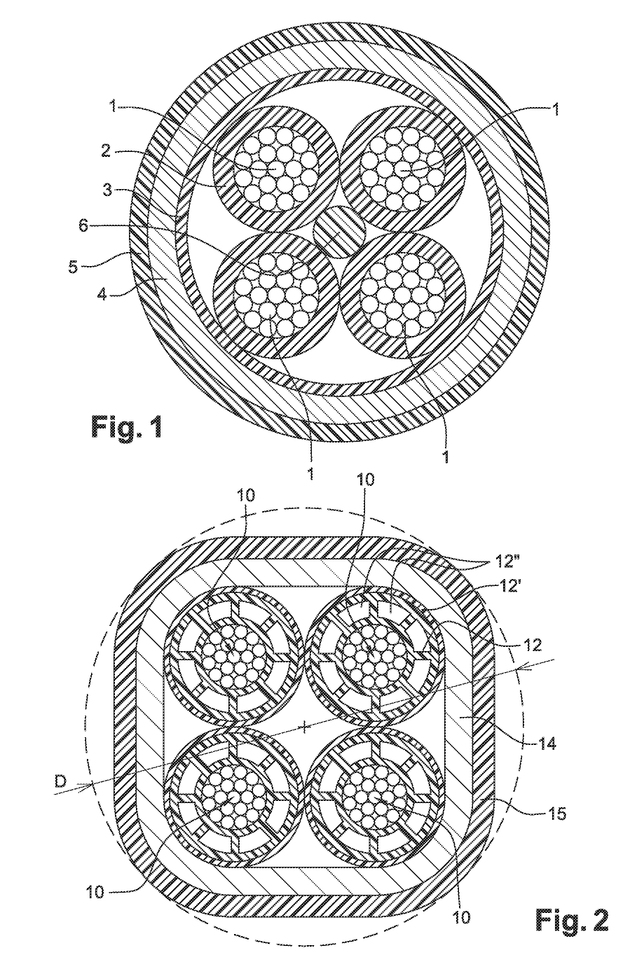

### DETAILED DESCRIPTION

As represented in FIG. 2, a data transmission cable intended for the aeronautical industry, according to the invention, comprises four bundles 10 consisting of 19 silver-coated copper conductor wires and each covered with an insulating layer 12, a shielding 14 consisting of a metallic fabric of braided silver-coated copper wires and surrounding the four bundles 10 and an outer sheath 15 surrounding the shielding 15.

The cable has no central mechanical support strength member for the bundles and no separating tape around the bundles.

The diameter of each bundle is equal to 0.625 mm with a tolerance of plus or minus 0.007 mm, each said bundle exhibiting a linear ohmic resistance less than or equal to 71.5 ohm/km and a linear weight less than or equal to 2.44 kg/km.

As specified in the standard cited previously, preferably, the silver coating has a minimum thickness of 1 micron, each bundle exhibits a minimum elongation of 10% and a breaking strain of 220 MPa.

The insulating layer 12 has no coloring pigments and is coated with a colored skin 12′, preferably approximately 0.05 mm thick.

The insulating layer comprises longitudinal aeration cells 12″ of trapezoidal cross section, evenly distributed and representing 40% of its total volume, and is made of perfluoromethoxy fluorocarbon (commonly known by its abbreviation MFA). As an example, the material called “Hyflon PFA M640”, marketed by the company Solvay Solexis, is used. This material exhibits a density of between 2.12 and 2.17 g/cm³ and an operating temperature of 255° C. The outer diameter of each bundle 10 equipped only with its insulating layer is 1.27 mm with a tolerance of plus or minus 0.03 mm.

The colored skin 12′ is made of fluorinated ethylene propylene (commonly known by its abbreviation FEP) which is a copolymer of hexafluoropropylene and of tetrafluoroethylene. As an example, the material called “Teflon FEP 106-N”, marketed by the company Dupont, is used. This material exhibits a density of between 2.12 and 2.17 g/cm³ and an operating temperature of 205° C. The outer diameter of each bundle 10 equipped with. its insulating layer 12, itself coated with the colored skin 12′, is 1.37 mm with a tolerance of plus or minus 0.03 mm.

The shielding 14 consisting of a metallic fabric comprises braided wires with a diameter of 0.12 mm, with a tolerance of plus or minus 0.003 mm. It has 24 yarns, 4 wires per yarn and a braiding angle of 27°. The nominal outer diameter of the shielding is approximately 3.85 mm.

The outer sheath 15 is advantageously made of ethylene tetrafluoroethylene (commonly known by its abbreviation ETFE). As an example, the material called “Tefzel 207”, marketed by the company Dupont, is used. This material exhibits a density of 1.7 g/cm³ and an operating temperature of 150° C. The total outer diameter D of the cable is 4.3 mm with a tolerance of plus or minus 0.2 mm.

A cable defined as above exhibits a low attenuation level, particularly optimized or a signal frequency greater than 20 MHz, while remaining limited at a signal frequency of less than 20 MHz.

The table below gives the attenuation safety margin. for the known cable EN 3375-011 C KT, cited above and for a cable according to the invention, this safety margin being defined as follows:

safety margin=100×[1−(greatest measured attenuation value/maximum attenuation defined by the standard EN 3375-011)]

| Signal frequency | Cable EN 3375-011 | Cable according to |
|---|---|---|
| (MHz) | C KL | the invention |
| 1 | 19.7% | 12.4% |
| 4 | 9.8% | 6.6% |
| 10 | 3.2% | 3.0% |
| 16 | 2.6% | 2.6% |
| 20 | 2.5% | 2.8% |
| 31.25 | 1.9% | 2.7% |
| 62.5 | 0.4% | 2.9% |
| 100 | 0.5% | 4.1% |

1. Data transmission cable, comprising:
four bundles each having 19 copper conductor wires and each covered with an insulating layer;
a shielding of a metallic copper fabric; and
an outer sheath,
wherein the diameter of each bundle is equal to 0.625 mm with a tolerance of plus or minus 0.007 mm,
said insulating layer has an aerated material, this aeration representing 40% of its total volume,
wherein said cable has no central mechanical support strength member for said bundles and no separating tape around said bundles.

2. Cable according to claim 1, wherein said insulating layer is provided with longitudinal aeration cells.

3. Cable according to claim 1, wherein said insulating layer has no coloring pigments and is coated with a colored skin.

4. Cable according to claim 3, wherein said colored skin is approximately 0.05 mm thick.

5. Cable according to claim 1, wherein said shielding of a metallic fabric comprises braided wires with a diameter of 0.12 mm, with a tolerance of plus or minus 0.003 mm.

6. Cable according to claim 5, wherein said conductor wires and said braided wires are coated with silver.

7. Cable according to claim 6, wherein the silver coating of the conductor wires has a minimum thickness of 1 micron.

8. Cable according to claim 1, wherein said outer sheath is made of ethylene tetrafluoroethylene (ETFE).
